(19) United States
(12) Patent Application Publication
(10) Pub. No.: US 2026/0282653 A1
(43) Pub. Date: Sep. 17, 2026

(54) DISPLAY DEVICE, ELECTRONIC DEVICE, AND METHOD FOR MANUFACTURING A DISPLAY DEVICE

(71) Applicant: Samsung Display Co., Ltd., Yongin-Si (KR)

(72) Inventors: EOK SU KIM, Yongin-si (KR); HYUNGJUN KIM, Yongin-si (KR)

(21) Appl. No.: 19/464,682

(22) Filed: Jan. 30, 2026

(30) Foreign Application Priority Data
Mar. 17, 2025 (KR) 10-2025-0033758

(51) Int. Cl. H10K 59/121; H10K 59/12

(52) U.S. Cl. CPC H10K 59/1213; H10K 59/1201

(57) ABSTRACT

A display device includes a substrate, a first lower circuit layer, and a first upper circuit layer. The substrate includes a display area and a non-display area adjacent to at least one side of the display area. The first lower circuit layer is disposed in the non-display area, and includes a lower transistor and a lower insulating layer. The first upper circuit layer is disposed on the first lower circuit layer, and includes an upper transistor and an upper insulating layer. A first contact hole is defined by a first sidewall of the lower insulating layer, and a second contact hole is defined by a second sidewall of the lower insulating layer. A first acute angle formed between the first sidewall and the substrate is smaller than a second acute angle formed between the second sidewall and the substrate.

This application claims priority to Korean Patent Application No. 10-2025-0033758, filed on Mar. 17, 2025, and all the benefits accruing therefrom under 35 U.S.C. § 119, the content of which in its entirety is herein incorporated by reference.

### BACKGROUND

### 1. Field

The present disclosure relates to a display device, an electronic device, and a method of manufacturing a display device. More particularly, the present disclosure pertains to a display device, an electronic device, and a manufacturing method thereof that provide improved reliability and are suitable for large-scale implementation by adopting a structure that prevents damage to the light-emitting layer and disconnection of electrodes and employing a process favorable to large-scale implementation.

### 2. Description of Related Art

An organic light-emitting display device has a self-luminous characteristic and, unlike a liquid crystal display device, does not require an external light source, allowing reductions in both thickness and weight. Additionally, organic light-emitting display devices exhibit high-quality characteristics such as low power consumption, high luminance, and fast response time.

Generally, a display device includes a display region through which images are displayed, and a non-display region in which circuits for driving the device are arranged. Recently, methods for maximizing the area of the display region have been actively researched.

### SUMMARY

The present disclosure provides a display device having improved reliability and enhanced display quality.

The present disclosure provides an electronic device including the display device with improved reliability and enhanced display quality.

The present disclosure provides a method of manufacturing a display device that offers improved reliability and enhanced display quality.

According to an embodiment, a display device comprises a substrate including a display area and a non-display area adjacent to at least one side of the display area, a first lower circuit layer disposed in the non-display area of the substrate, and a first upper circuit layer disposed on the first lower circuit layer. The first lower circuit layer includes a lower transistor and a lower insulating layer, and the first upper circuit layer includes an upper transistor and an upper insulating layer. A first contact hole is defined by a first sidewall of the lower insulating layer, and a second contact hole is defined by a second sidewall of the lower insulating layer. The first contact hole overlaps at least a portion of an active layer of the upper transistor, and the second contact hole does not overlap the active layer of the upper transistor. A first acute angle formed between the first sidewall and the substrate is smaller than a second acute angle formed between the second sidewall and the substrate.

In an embodiment, the first acute angle may be greater than or equal to about 40° and smaller than or equal to about 60°.

In an embodiment, the second acute angle may be greater than or equal to about 70° and smaller than or equal to about 90°.

In an embodiment, the first lower circuit layer may further include a lower wiring layer disposed between the substrate and the lower transistor. The display device may further include a first pattern connected, through the first contact hole, to at least one of a first portion of the lower transistor and the lower wiring layer, and a second pattern connected, through the second contact hole, to at least one of a second portion of the lower transistor and the lower wiring layer.

In an embodiment, the first pattern and the second pattern may be provided as an integral structure.

In an embodiment, at least a portion of the lower transistor may overlap the first contact hole. At least a portion of the lower wiring layer may overlap the second contact hole.

In an embodiment, at least a portion of the lower wiring layer may overlap the first contact hole. At least a portion of the lower transistor may overlap the second contact hole.

In an embodiment, the lower transistor may include a first lower transistor and a second lower transistor. At least a portion of the first lower transistor may overlap the first contact hole. At least a portion of the second lower transistor may overlap the second contact hole.

In an embodiment, a third contact hole may be defined by a third sidewall of the lower insulating layer. The third contact hole may overlap at least a second portion of the active layer of the upper transistor. A first portion of the lower transistor may overlap the first contact hole, and a second portion of the lower transistor may overlap the third contact hole. A third acute angle formed between the third sidewall and the substrate may be smaller than the second acute angle.

In an embodiment, a fourth contact hole may be defined by a fourth sidewall of the upper insulating layer. The fourth contact hole may overlap at least a portion of the active layer of the upper transistor. A fourth acute angle formed between the fourth sidewall and the substrate may be greater than the first acute angle.

In an embodiment, the display device may further comprise a second lower circuit layer disposed in the display area of the substrate and including a pixel transistor and the lower insulating layer, and a second upper circuit layer disposed on the second lower circuit layer and including a capacitor and the upper insulating layer. A fifth contact hole may be defined by a fifth sidewall of the lower insulating layer. The fifth contact hole may overlap at least a portion of the capacitor. A fifth acute angle formed between the fifth sidewall and the substrate may be smaller than the second acute angle.

In an embodiment, the display device may further comprise a second lower circuit layer disposed in the non-display area of the substrate and including a second lower transistor and the lower insulating layer, and a second upper circuit layer disposed on the second lower circuit layer and including a capacitor and the upper insulating layer. A fifth contact hole may be defined by a fifth sidewall of the lower insulating layer. The fifth contact hole may overlap at least a portion of the capacitor. A fifth acute angle formed between the fifth sidewall and the substrate may be greater than the first acute angle.

In an embodiment, the upper transistor may include a first upper transistor and a second upper transistor. A sixth contact hole may be defined by a sixth sidewall of the lower insulating layer. The first contact hole may overlap at least a portion of an active layer of the first upper transistor, and the second contact hole may overlap at least a portion of an active layer of the second upper transistor. A sixth acute angle formed between the sixth sidewall and the substrate may be smaller than the second acute angle.

According to an embodiment, a method of manufacturing a display device comprises preparing a substrate which includes a display area and a non-display area adjacent to at least one side of the display area, forming a lower transistor and a preliminary lower insulating layer on the substrate, forming a lower insulating layer including a first sidewall, by which a first contact hole is defined, and a second sidewall, by which a second contact hole is defined, by patterning the lower insulating layer, and forming an upper transistor and an upper insulating layer on the lower transistor and the lower insulating layer. The first contact hole overlaps at least a portion of an active layer of the upper transistor, and the second contact hole does not overlap the active layer of the upper transistor. A first acute angle formed between the first sidewall and the substrate is smaller than a second acute angle formed between the second sidewall and the substrate.

In an embodiment, the first acute angle may be greater than or equal to about 40° and smaller than or equal to about 60°.

In an embodiment, the second acute angle may be greater than or equal to about 70° and smaller than or equal to about 90°.

In an embodiment, the step of forming the first sidewall may include forming a first preliminary photoresist on the preliminary lower insulating layer, and performing a heat treatment on the first preliminary photoresist. An opening corresponding to the first contact hole may be defined in the first preliminary photoresist.

In an embodiment, the step of forming the second sidewall may include forming a second photoresist after performing the heat treatment on the first preliminary photoresist.

According to an embodiment, an electronic device comprises a processor, and a display device receiving image data signal from the processor and providing image corresponding to the received image data signal. The display device comprises a substrate including a display area and a non-display area adjacent to at least one side of the display area, a first lower circuit layer disposed in the non-display area and including a lower transistor and a lower insulating layer, and a first upper circuit layer disposed on the first lower circuit layer and including an upper transistor and an upper insulating layer. A first contact hole is defined by a first sidewall of the lower insulating layer, and a second contact hole is defined by a second sidewall of the lower insulating layer. The first contact hole overlaps at least a portion of an active layer of the upper transistor, and the second contact hole does not overlap the active layer of the upper transistor. A first acute angle formed between the first sidewall and the substrate is smaller than a second acute angle formed between the second sidewall and the substrate.

In an embodiment, the electronic device may further include a memory storing data required for an operation of the display device or the processor, and a power conversion module configured to generate or supply power.

According to embodiments of the present disclosure, a display device, an electronic device, and a method of manufacturing the display device that includes a transistor having a planar structure and exhibits electrical stability are provided. Accordingly, the area of the non-display region is reduced, thereby improving the reliability and enhancing the display quality.

### BRIEF DESCRIPTION OF THE DRAWINGS

The above and other features of the present disclosure will become apparent and more readily appreciated from the following description of the embodiments, taken in conjunction with the accompanying drawings.

FIG. 1 is a plan view illustrating a display device according to an embodiment of the disclosure.

FIG. 2 is a cross-sectional view illustrating a display device according to an embodiment.

FIG. 3 is an enlarged view of region AA of FIG. 2.

FIG. 4 is an enlarged view of region BB of FIG. 2.

FIG. 5 is a cross-sectional view illustrating a display device according to an embodiment.

FIG. 6 is a cross-sectional view illustrating a display device according to an embodiment.

FIG. 7 is a cross-sectional view illustrating a display device according to an embodiment.

FIG. 8 is a cross-sectional view illustrating a display device according to an embodiment.

FIG. 9 is a flow chart illustrating a method of manufacturing a display device according to an embodiment.

FIGS. 10A to 10F are schematic views respectively illustrating steps of a method of manufacturing a display device.

FIG. 11 is a block diagram of an electronic device according to an embodiment.

FIG. 12 illustrates schematic views of electronic devices according to various embodiments.

### DETAILED DESCRIPTION

Hereinafter, specific embodiments of the present disclosure are explained in detail with reference to the accompanying drawings. Like numerals refer to like elements throughout. The embodiments may have a variety of forms, but the present disclosure shall by no means be construed as being limited to the described embodiments. Rather, the present disclosure shall be construed to encompass all forms, variations, equivalents and substitutes covered by the technical ideas and scope of the present disclosure. Accordingly, the embodiments are described herein, by referring to the figures, to explain features of the present disclosure.

In the present specification, when an element (or region, layer, portion, etc.) is described as being “on,” “connected to,” or “coupled to” another element, it may be directly disposed on, connected to, or coupled to the other element, or an intervening element may be present between them.

Identical reference numerals denote identical or corresponding components. In the drawings, thicknesses, proportions, and dimensions of components may be exaggerated for clarity of illustration. The term “and/or” encompasses any and all combinations of one or more of the associated components.

The terms, such as “first,” “second,” etc., may be used to describe various components, but such terms are merely used to distinguish one component from another and should not be construed as limiting. For example, without departing from the scope of the present disclosure, a “first” component may be referred to as a “second” component and similarly, a “second” component may be referred to as a “first” component. Unless clearly stated otherwise by context, singular expressions include the plural forms and vice versa.

Additionally, terms such as “below,” “under,” “above,” or “over” are used to describe relative positions between components as illustrated in the drawings. These terms are used as relative concepts based on the depicted orientation and may include both directions along and opposite to the direction shown.

The terms “comprise” or “include” and variations thereof are intended to specify the presence of stated features, numbers, steps, operations, components, or elements, but do not preclude the presence or addition of one or more other features, numbers, steps, operations, components, elements, or groups thereof.

Unless otherwise defined, all terms used herein (including technical and scientific terms) have the same meaning as commonly understood by one of ordinary skill in the art to which the present disclosure pertains. Terms such as those defined in commonly used dictionaries should be interpreted in the context of the relevant art and are not to be interpreted in an overly idealized or formal sense unless expressly defined herein.

Where steps of a method are described in a particular order, the steps may be performed in an order different from that described unless explicitly stated otherwise. For example, two steps that are described consecutively may be executed substantially simultaneously, or in reverse order.

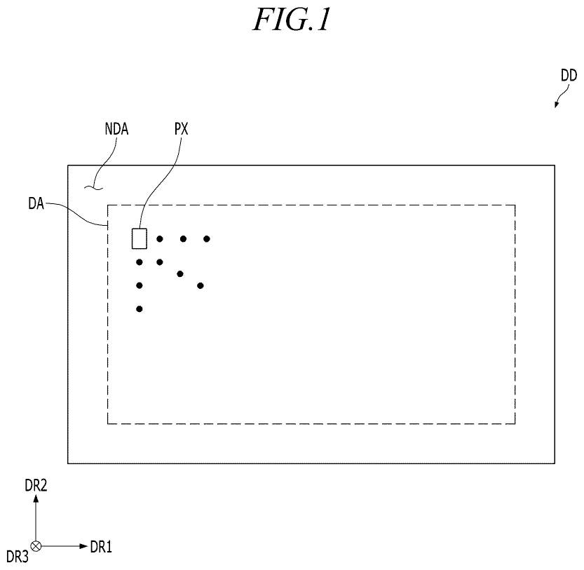

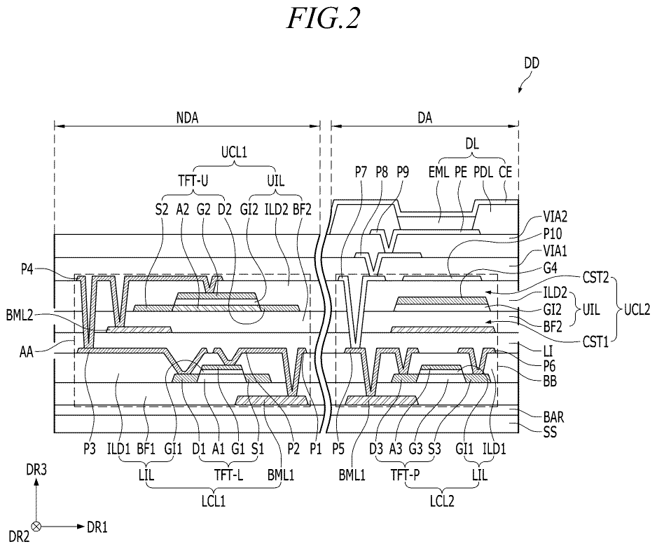

First to third directions DR1, DR2, DR3 may be defined. The first direction DR1 and the second direction DR2 may be directions intersecting each other on the plane of a display device DD as shown in FIG. 1. The third direction DR3 may correspond to the thickness direction of the display device DD as illustrated in FIG. 2.

In this specification, the expression “in a plan view” may refer to a view in the third direction DR3, i.e., a top-down view from above a component. Descriptions based on specific directions may include not only the direction depicted in the drawings but also the opposite direction thereto.

Hereinafter, embodiments of the present disclosure will be described with reference to the drawings. The same or corresponding elements are given the same reference numerals, and redundant explanations thereof will be omitted.

FIG. 1 is a plan view illustrating a display device according to an embodiment of the present disclosure. Referring to FIG. 1, a display device DD according to an embodiment may include a display area DA and a non-display area NDA disposed adjacent to at least one side of the display area DA. The display area DA and the non-display area NDA may be regions defined on a substrate SS (see FIG. 2).

The display area DA is a region through which images are displayed, and a plurality of pixels PX may be arranged in the display area DA. The display area DA may have various shapes such as circular, elliptical, polygonal, or the shape of a specific figure.

A plurality of pixels PX that include light-emitting diodes, such as organic light-emitting diodes, may be arranged in the display area DA. The pixels PX may include transistors configured to control the light-emitting diodes. A single pixel PX may include at least one or more transistors.

Various wirings for transferring electrical signals to be applied to the plurality of pixels PX in the display area DA may be disposed in the non-display area NDA. The non-display area NDA may include transistors (not shown), which may be part of a circuit section (not shown) configured to control the electrical signals applied to the plurality of pixels PX in the display area DA.

In an embodiment, the display area DA and the non-display area NDA may be regions defined on the substrate SS (see FIG. 2). The display area DA and the non-display area NDA may also correspond to regions that are similarly applied to components disposed on the substrate SS (see FIG. 2).

Hereinafter, for convenience of explanation, the display device DD of the present disclosure is described as including an organic light-emitting display device. However, the display device DD of the disclosure is not limited thereto. For example, the display device DD may include an inorganic light-emitting display or a quantum dot light-emitting display. For example, a light-emitting layer included in the display element of the display device DD may include an organic material, an inorganic material, quantum dots, both an organic material and quantum dots, or both an inorganic material and quantum dots.

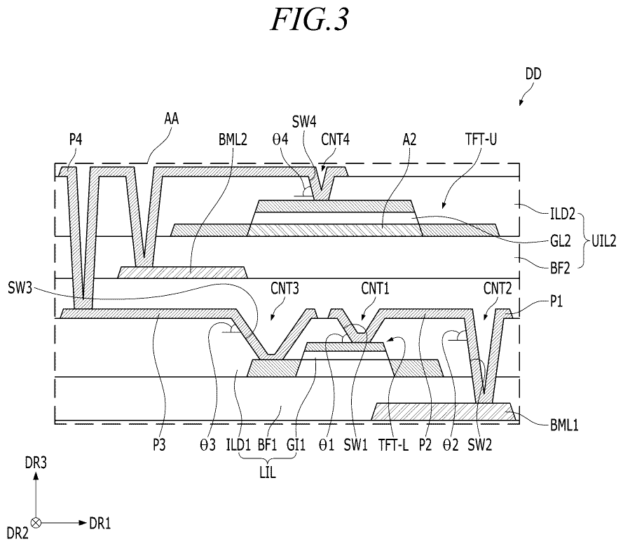

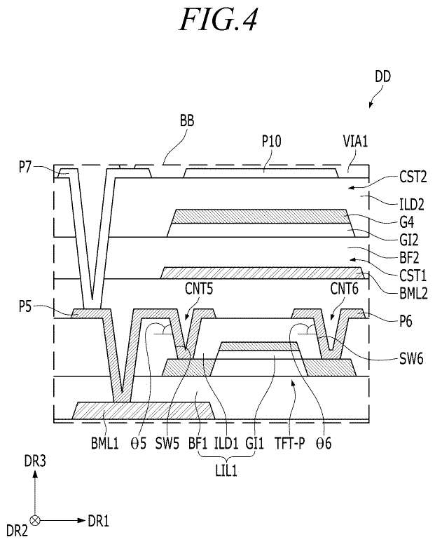

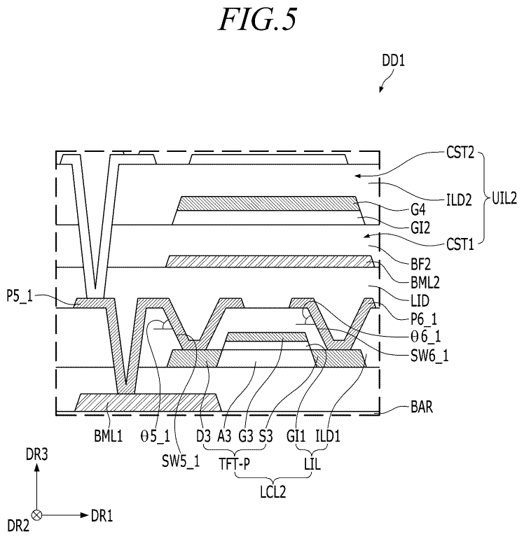

FIG. 2 is a cross-sectional view illustrating a display device according to an embodiment. FIG. 3 is an enlarged view of region AA of FIG. 2. FIG. 4 is an enlarged view of region BB of FIG. 2. FIG. 5 is a cross-sectional view illustrating a display device according to an embodiment.

Referring to FIG. 2, a display device DD according to an embodiment may include a substrate SS, a barrier layer BAR, a first lower circuit layer LCL1, a first upper circuit layer UCL1, a second lower circuit layer LCL2, a second upper circuit layer UCL2, and a display layer DL.

The substrate SS may include various materials such as glass, metal, or plastic. In an embodiment, the substrate SS may be a flexible substrate. For example, the substrate SS may include a polymer resin such as polyethersulfone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), or cellulose acetate propionate (CAP).

The barrier layer BAR may include an inorganic insulating material. Examples of inorganic insulating materials that may be used for the barrier layer BAR may include silicon oxide, silicon nitride, or silicon oxynitride. The barrier layer BAR may have a single-layer or multilayer structure, and may be configured to prevent foreign substances from penetrating into the display device DD.

The first lower circuit layer LCL1 may be disposed in the non-display area NDA and may include a lower insulating layer LIL and a lower transistor TFT-L. The lower insulating layer LIL may include a first buffer layer BF1, a first gate insulating layer GI1, and a first insulating layer ILD1, all of which may overlap the non-display area NDA.

The first buffer layer BF1 may be disposed between the substrate SS and the lower transistor TFT-L. The first buffer layer BF1 may serve to prevent impurity ions from diffusing from the upper surface of the substrate SS, to prevent moisture or external air from penetrating, and to planarize the surface. In an embodiment, the first buffer layer BF1 may include an inorganic material such as silicon oxide, silicon nitride, silicon oxynitride, aluminum oxide, aluminum nitride, titanium oxide, or titanium nitride, or of an organic material such as polyimide, polyester, or acrylic, or a laminate thereof.

The first insulating layer ILD1 may be disposed on the first buffer layer BF1. Patterns P1 to P6 configured to electrically connect components disposed on the substrate SS and an interlayer insulating layer LI may be provided on the first insulating layer ILD1.

The lower transistor TFT-L may include an active layer A1, a gate electrode G1, a source electrode S1, and a drain electrode D1. The active layer A1 of the lower transistor TFT-L may be a region between the source electrode S1 and the drain electrode D1. The first gate insulating layer GI1 may be disposed between the gate electrode G1 and the active layer A1 to insulate the gate electrode from the active layer A1. Although FIG. 2 shows the first gate insulating layer GI1 is disposed on the active layer A1 of the lower transistor TFT-L and is patterned to have the same as or similar shape to the gate electrode G1, the configuration is not limited thereto. For example, the first gate insulating layer GI1 may cover the active layer A1 of the lower transistor TFT-L and be disposed on the first buffer layer BF1. The lower transistor TFT-L may be one of the transistors constituting a driving circuit configured for driving the display device DD.

The active layer A1 may be disposed on the first buffer layer BF1, and include an inorganic semiconductor such as amorphous silicon or polysilicon, or an organic semiconductor. In an embodiment, the active layer A1 may include an oxide semiconductor. For example, the oxide semiconductor may include an oxide of a material selected from groups 12, 13, or 14 of the periodic table, such as zinc (Zn), indium (In), gallium (Ga), tin (Sn), cadmium (Cd), germanium (Ge), or hafnium (Hf), or a combination thereof.

Referring to FIG. 3, in an embodiment, to reduce the area of the non-display area NDA (see FIG. 2), at least a portion of an upper transistor TFT-U and at least a portion of the lower transistor TFT-L of the display device DD may be vertically stacked so as to overlap each other in a plan view. A more detailed description of this configuration will be provided later.

In an embodiment, the lower insulating layer LIL may include first to third sidewalls SW1, SW2, SW3. These sidewalls SW1, SW2, SW3 may be structures formed in at least one of the first buffer layer BF1, the first insulating layer ILD1, and the gate insulating layer GI1 included in the lower insulating layer LIL. For example, the first sidewall SW1 may be a structure formed in the first insulating layer ILD1 of the lower insulating layer LIL. The second sidewall SW2 may be a structure formed in both the first buffer layer BF1 and the first insulating layer ILD1.

In an embodiment, a first contact hole CNT1 may be defined by the first sidewall SW1 of the lower insulating layer LIL. In an embodiment, a second contact hole CNT2 may be defined by the second sidewall SW2 of the lower insulating layer LIL. In an embodiment, a third contact hole CNT3 may be defined by the third sidewall SW3 of the lower insulating layer LIL.

In an embodiment, in a plan view, the first contact hole CNT1 and the third contact hole CNT3 may overlap at least a portion of an active layer A2 of the upper transistor TFT-U, which is disposed between a source electrode S2 and a drain electrode D2 of the upper transistor TFT-U.

In an embodiment, a first acute angle θ1 formed between the first sidewall SW1, by which the first contact hole CNT1 is defined, and the substrate SS may be smaller than a second acute angle θ2 formed between the second sidewall SW2, by which the second contact hole CNT2 is defined, and the substrate SS. In an embodiment, a third acute angle θ3 formed between the third sidewall SW3, by which the third contact hole CNT3 is defined, and the substrate SS may be smaller than the second acute angle θ2.

In the display device DD according to an embodiment of the disclosure, the first contact hole CNT1 may overlap at least a portion of the active layer A2 of the upper transistor TFT-U in a plan view. Additionally, the first sidewall SW1, by which the first contact hole CNT1 is defined, and the third sidewall SW3, by which the third contact hole CNT3 is defined, may form acute angles with the substrate SS that are smaller than the acute angle formed between the substrate SS and the second sidewall SW2, which does not overlap the active layer A2. Accordingly, the active layer A2 of the upper transistor TFT-U, which is disposed on the first and third contact holes CNT1, CNT3 which are defined by the first side wall SW1 and the third side wall SW3 having gradual slopes, may be formed in a planar manner. As a result, the electrical stability of the upper transistor TFT-U may be enhanced, thereby improving the reliability of the display device DD.

In this specification, when a structure is described as having a “gradual” or “steep” slope, it is to be interpreted that the acute angle formed between the structure and the substrate is relatively small or large, respectively.

If a contact hole is defined by a certain sidewall having a gradual slope, a component disposed above and overlapping the contact hole in a plan view may be formed relatively flat.

Conversely, if a contact hole is defined by a certain sidewall having a steep slope, the area occupied by the contact hole in a plan view may be smaller than that of another contact hole defined by a sidewall having a more gradual slope.

In an embodiment, the first acute angle θ1 formed between the first sidewall SW1 and the substrate SS may be greater than or equal to about 40° and smaller than or equal to about 60°.

In an embodiment, the third acute angle θ3 formed between the third sidewall SW3 and the substrate SS may be greater than or equal to about 40° and smaller than or equal to about 60°.

In an embodiment, the second acute angle θ2 formed between the second sidewall SW2 and the substrate SS may be greater than or equal to about 70° and smaller than or equal to about 90°.

In an embodiment of the disclosure, the second acute angle θ2 may be greater than the first and third acute angles θ1, θ3. The second contact hole CNT2, which does not overlap the active layer A2 of the upper transistor TFT-U in a plan view, is defined by the second sidewall SW2, which forms a relatively greater acute angle than the first and third acute angles θ1, θ3. As a result, the area occupied by the second contact hole CNT2 in a plan view may be relatively small, and the display device DD may have a reduced area for the non-display region NDA. Therefore, an increased area for the display region DA, proportional to the reduction in the area of the non-display region NDA, may be secured, thereby enhancing the display quality of the display device DD.

In an embodiment, the first lower circuit layer LCL1 may further include a lower wiring layer BML1. In an embodiment, the second lower circuit layer LCL2 may further include a lower wiring layer BML1.

In an embodiment, the lower wiring layer BML1 may be configured to be electrically connected to a transistor or another wiring disposed in the display device DD. However, the embodiment is not limited thereto. For example, the lower wiring layer BML1 may also serve to prevent or minimize the influence of external light or an electric field generated in the substrate from reaching at least a portion of the first lower circuit layer LCL1 and at least a portion of the second lower circuit layer LCL2. For example, the lower wiring layer BML1 may also be applied with a back-bias technique (or sync technique) to move the threshold voltage of the lower transistor TFT-L in either a negative or positive direction.

In an embodiment, a first pattern P1 may be connected, via the first contact hole CNT1, to at least one of a first portion of the lower transistor TFT-L and the lower wiring layer BML1.

In an embodiment, a second pattern P2 may be connected, via the second contact hole CNT2, to at least one of a second portion of the lower transistor TFT-L and the lower wiring layer BML1.

In an embodiment, the first pattern P1 may be connected to the lower wiring layer BML1 through the second contact hole CNT2, and the second pattern P2 may be connected to the gate electrode G2 of the lower transistor TFT-L through the first contact hole CNT1.

In an embodiment, the first pattern P1 and the second pattern P2 may be separated from each other, or may be provided as a single integral structure. The first pattern P1 and the second pattern P2 may contact the lower wiring layer BML1 and the lower transistor TFT-L through the first contact hole CNT1 and the second contact hole CNT2, respectively, thereby electrically connecting the lower wiring layer BML1 to the lower transistor TFT-L.

Although FIG. 2 illustrates the lower transistor TFT-L, the lower wiring layer BML1, an upper wiring layer BML2, and the upper transistor TFT-U as being electrically connected through the first to fourth patterns P1-P4, the embodiment of the disclosure is not limited thereto. For example, some of the lower transistor TFT-L, the lower wiring layer BML1, the upper wiring layer BML2, and the upper transistor TFT-U may be directly connected to each other, indirectly connected through the patterns P1-P4, or not connected at all. The connection relationships among the lower transistor TFT-L, the lower wiring layer BML1, the upper wiring layer BML2, and the upper transistor TFT-U may vary depending on the circuit configuration.

The first upper circuit layer UCL1 may be disposed in the non-display area NDA and may be disposed on the first lower circuit layer LCL1. The first upper circuit layer UCL1 may include the upper transistor TFT-U and an upper insulating layer UIL. In an embodiment, the first upper circuit layer UCL1 may include at least one upper transistor TFT-U.

In the display device DD according to an embodiment of the disclosure, by placing at least one upper transistor TFT-U in the first upper circuit layer UCL1 on the first lower circuit layer LCL1 and within the non-display area NDA, the area of the non-display region NDA may be reduced. As a result, an increased display area DA, proportional to the reduction in the non-display area NDA, may be secured, thereby improving the display quality of the display device DD.

In an embodiment, the upper insulating layer UIL may include a second gate insulating layer GI2, a second insulating layer ILD2, and a second buffer layer BF2. In an embodiment, a fourth contact hole CNT4 may be defined by a fourth sidewall SW4 of the upper insulating layer UIL. In an embodiment, a fourth acute angle θ4 formed between the fourth sidewall SW4 and the substrate SS may be greater than the first acute angle θ1.

Referring to FIGS. 2 and 4, a second lower circuit layer LCL2 and a second upper circuit layer UCL2 may be disposed in the display area DA of the substrate SS. In addition, patterns P5-P10, which electrically connect various components, may be arranged in the display area DA.

The second lower circuit layer LCL2 may be disposed in the display area DA and may include a pixel transistor TFT-P and a lower insulating layer LIL. The second upper circuit layer UCL2 may be disposed on the second lower circuit layer LCL2 and may include a first capacitor CST1, a second capacitor CST2, and an upper insulating layer UIL.

In an embodiment, the first capacitor CST1 may be formed between the upper wiring layer BML2 and a fourth gate electrode G4. In an embodiment, the second capacitor CST2 may be formed between the fourth gate electrode G4 and the tenth pattern P10.

The lower insulating layer LIL, overlapping the display area DA, may include a fifth sidewall SW5 and a sixth sidewall SW6. A fifth contact hole CNT5 may be defined by the fifth sidewall SW5, and a sixth contact hole CNT6 may be defined by the sixth sidewall SW6.

In an embodiment, the fifth contact hole CNT5 may overlap at least a portion of the capacitors CST1, CST2 in a plan view. In an embodiment, the sixth contact hole CNT6 may overlap at least a portion of the capacitors CST1, CST2 in a plan view.

In an embodiment, a fifth acute angle θ5 formed between the fifth sidewall SW5 and the substrate SS may be greater than the first acute angle θ1. In an embodiment, a sixth acute angle θ6 formed between the sixth sidewall SW6 and the substrate SS may be greater than the first acute angle θ1.

The fifth acute angle θ5 and the sixth acute angle θ6 may vary, for example, to have a value that is greater or smaller than the first acute angle θ1, depending on the size of the pixel PX or the size of the display area DA. For example, if it is necessary to reduce the size of the pixel PX to improve the resolution of the display device DD, the fifth acute angle θ5 and the sixth acute angle θ6 may be greater than the first acute angle θ1.

However, the embodiment is not limited thereto. Referring to FIG. 5, the fifth acute angles θ5_1 and the sixth acute angle θ6_1 may be smaller than the first acute angle θ1 (see FIG. 3). In the display device DD1, the fifth sidewall SW5_1 and the sixth sidewall SW6_1 having gradual slopes may be disposed below the capacitors CST1, CST2 to overlap the capacitors CST1, CST2 in a plan view. Accordingly, the components forming the capacitors CST1, CST2 may be formed in a planar manner, and the electrical stability of the display device DD1 may be improved.

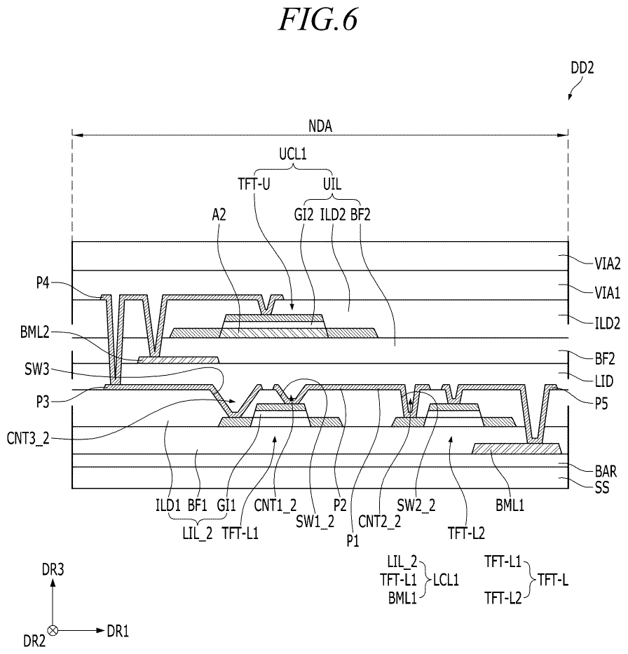

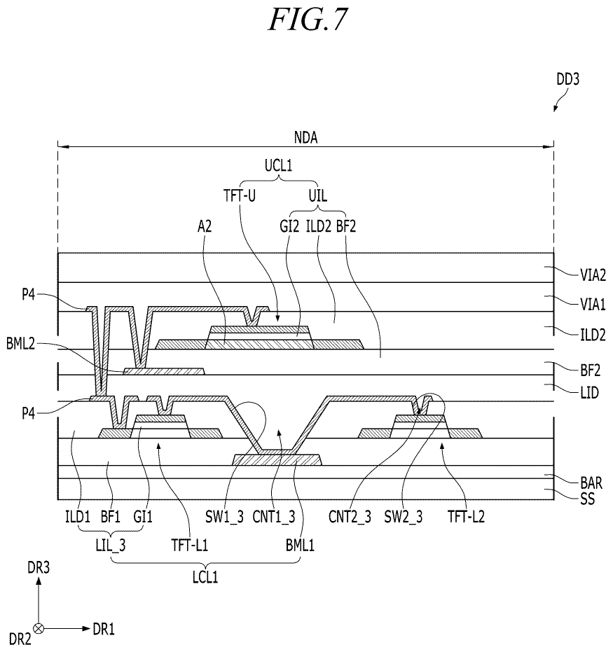

FIG. 6 is a cross-sectional view illustrating a display device according to an embodiment. FIG. 7 is a cross-sectional view illustrating a display device according to an embodiment. FIG. 8 is a cross-sectional view illustrating a display device according to an embodiment.

Referring to FIG. 6, in an embodiment, a first contact hole CNT1_2 and a third contact hole CNT3_2 may overlap at least a portion of a first lower transistor TFT-L1 among the lower transistors TFT-L in a plan view, and a second contact hole CNT2_2 may overlap at least a portion of a second lower transistor TFT-L2 among the lower transistors TFT-L in a plan view.

According to an embodiment, the first contact hole CNT1_2, which overlaps at least a portion of the active layer A2 of the upper transistor TFT-U in a plan view, may be defined by a first sidewall SW1_2 of the lower insulating layer LIL_2 having a gradual slope. The third contact hole CNT3_2, which overlaps at least a portion of the active layer A2 of the upper transistor TFT-U in a plan view, may be defined by a third sidewall SW3_2 of the lower insulating layer LIL_2 having a gradual slope. Accordingly, the active layer A2 of the upper transistor TFT-U may be formed in a planar configuration. The second contact hole CNT2_2 may be defined by a second sidewall SW2_2 of the lower insulating layer LIL_2 having a steep slope, allowing the display device DD2 according to an embodiment to have a reduced non-display area NDA.

Referring to FIG. 7, in an embodiment, the first contact hole CNT1_3 may overlap at least a portion of the lower wiring layer BML1 in a plan view, and the second contact hole CNT2_3 may overlap at least a portion of the second lower transistor TFT-L2 in a plan view.

According to an embodiment, the first contact hole CNT1_3, which overlaps the active layer A2 of the upper transistor TFT-U in a plan view, may be formed by the first sidewall SW1_3 of the lower insulating layer LIL having a gradual slope, and the active layer A2 of the upper transistor TFT-U may be formed in a planar configuration. The second contact hole CNT2_3, which does not overlap the active layer A2 in a plan view, may be formed by the second sidewall SW2_3 of the lower insulating layer LIL having a steep slope, enabling the display device DD3 to have a reduced non-display area NDA.

Referring to FIG. 8, in an embodiment, the upper transistor TFT-U may include a first upper transistor TFT-U1 and a second upper transistor TFT-U2. In the lower insulating layer LIL_4, a first contact hole CNT1_4 may be defined by a first sidewall SW1_4, a second contact hole CNT2_4 may be defined by a second sidewall SW2_4, and a sixth contact hole CNT6_4 may be defined by a sixth sidewall SW6_4.

According to an embodiment, the first contact hole CNT1_4, which overlaps the active layer A2 of the first upper transistor TFT-U1 in a plan view, may be formed by the first sidewall SW1_4 having a gradual slope. The sixth contact hole CNT6_4, which overlaps the active layer A4 of the second upper transistor TFT-U2 in a plan view, may be formed by the sixth sidewall SW6_4 having a gradual slope. The active layer A2 of the first upper transistor TFT-U1 and the active layer A4 of the second upper transistor TFT-U2 may have planar configurations and may be electrically stable. The upper transistor TFT-U and the lower transistor TFT-L may be disposed to overlap at least partially in a plan view. The second contact hole CNT2_4, which does not overlap either of the active layer A2 of the first upper transistor TFT-U1 or the active layer A4 of the second upper transistor TFT-U2 in a plan view, may be formed by the second sidewall SW2_4 having a steep slope, thereby allowing the display device DD4 to have a reduced non-display area NDA.

In the display device according to an embodiment of the disclosure, a lower contact hole that overlaps at least a portion of the active layer of the upper transistor in a plan view may be formed or defined by a sidewall of the lower insulating layer having a gradual slope. As a result, the active layer of the upper transistor may have a planar shape and exhibit electrical stability. In addition, transistors and wiring layers disposed in the non-display area of the substrate may be arranged to at least partially overlap each other, and a contact hole that does not overlap the active layer of the upper transistor may be formed or defined by a sidewall of the lower insulating layer having a steep slope. This configuration may reduce the area of the non-display region, improve the reliability of the display device, and enhance display quality.

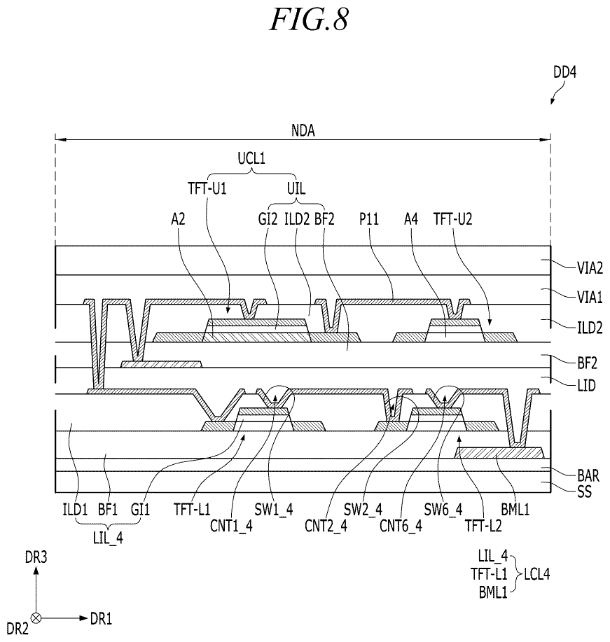

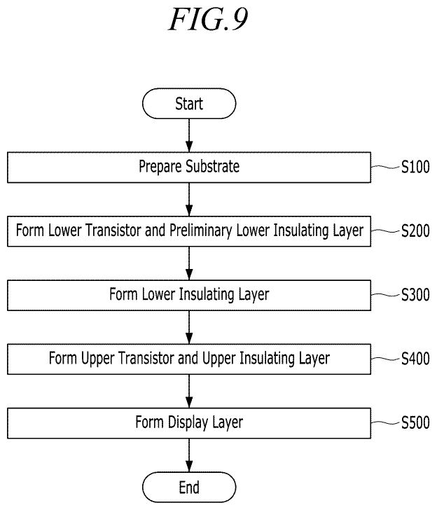

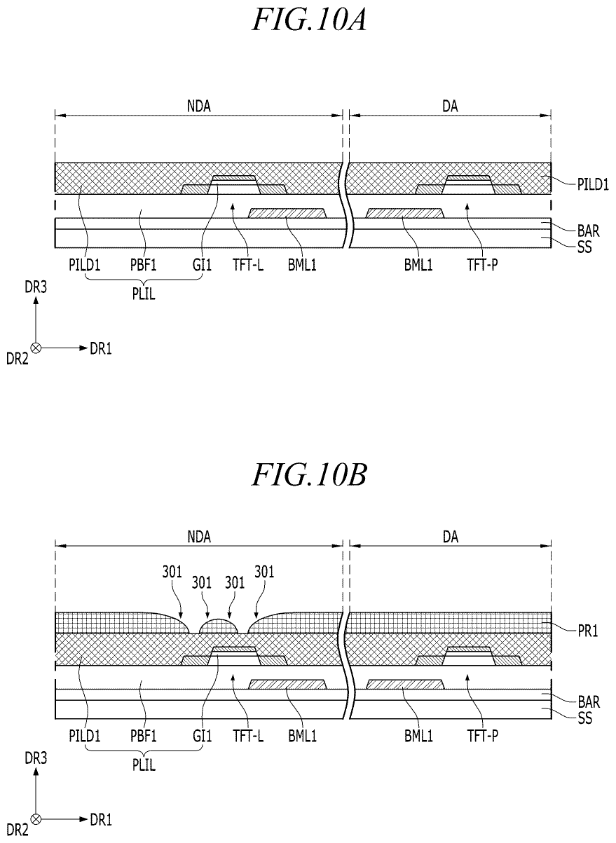

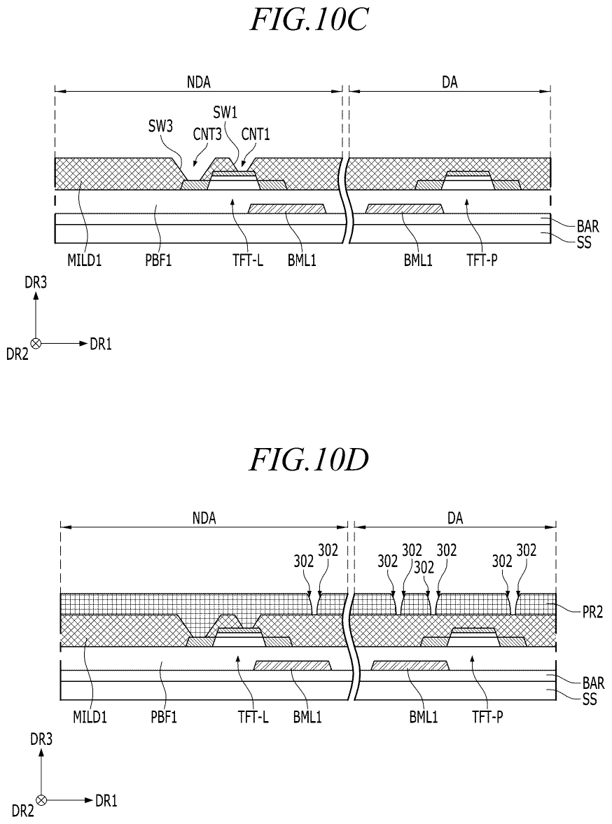

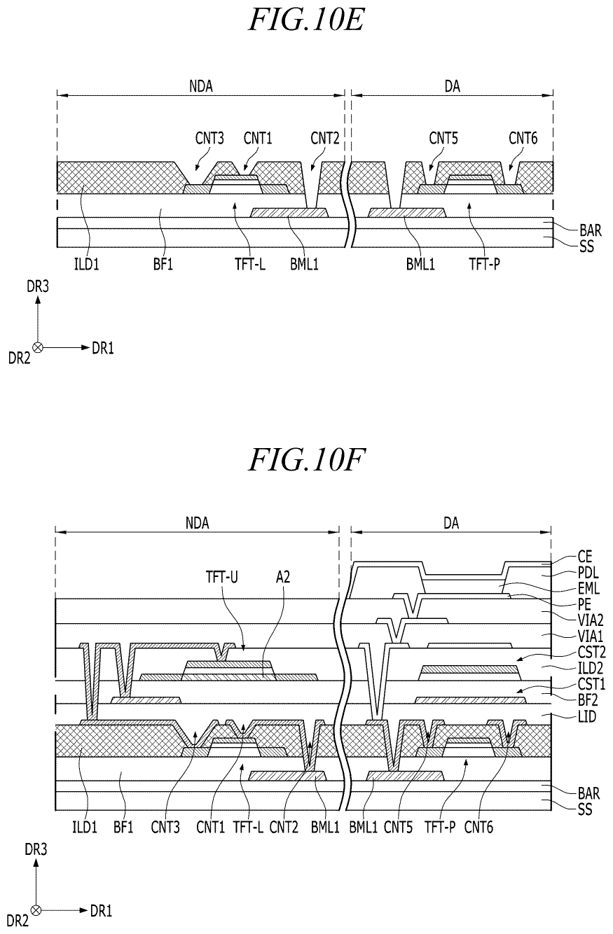

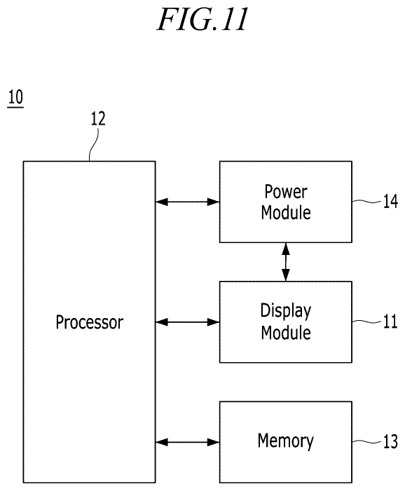

FIG. 9 is a flow chart illustrating a method of manufacturing a display device according to an embodiment. FIGS. 10A to 10F are schematic views respectively illustrating steps of the method of manufacturing a display device. Hereinafter, a method of manufacturing a display device according to an embodiment will be described with reference to FIGS. 9 through 10F. In the following description of the manufacturing method, redundant descriptions with respect to the display device already described above will be omitted.

Referring to FIG. 9, the method of manufacturing a display device according to an embodiment may include preparing a substrate (S100), forming a lower transistor and a preliminary lower insulating layer (S200), forming a lower insulating layer (S300), forming an upper transistor and an upper insulating layer (S400), and forming a display layer (S500).

FIG. 10A illustrates a portion of the display device with steps S100 and S200 completed in the method of manufacturing a display device. Referring to FIG. 10A, a substrate SS, a barrier layer BAR, a lower wiring layer BML1, a lower transistor TFT-L, and a preliminary lower insulating layer PLIL may be sequentially provided. In an embodiment, the preliminary lower insulating layer PLIL may include a first preliminary buffer layer PBF1, a first gate insulating layer GI1, and a first preliminary insulating layer PILD1.

Referring to FIGS. 10B and 10C, which depict step S300, a first photoresist PR1 may first be formed on the preliminary lower insulating layer PLIL. The first photoresist PR1 may have gradual side surfaces 301 at positions corresponding to a first contact hole CNT1 and a third contact hole CNT3 (see FIG. 2). Although not illustrated, forming the first photoresist PR1 may include forming a first preliminary photoresist (not shown) on the preliminary lower insulating layer PLIL and then heat-treating the first preliminary photoresist. Specifically, the first preliminary photoresist (not shown) may be patterned to form openings at positions corresponding to the first contact hole CNT1 and the third contact hole CNT3, and then be heat-treated in order for the side surfaces of the openings to transform into the gradual side surfaces 301.

Subsequently, a portion of the preliminary lower insulating layer PLIL may be etched to form a first intermediate insulating layer MILD1 having a first sidewall SW1 and a third sidewall SW3. The first contact hole CNT1 may be defined by the first sidewall SW1, and the third contact hole CNT3 may be defined by the third sidewall SW3. The first and third sidewalls SW1, SW3 may be formed to correspond to the gradual side surfaces 301 of the first photoresist PR1 and therefore have gradual slopes.

According to the method of manufacturing a display device in an embodiment, a first acute angle θ1 formed between the first sidewall SW1 and the substrate SS may be greater than or equal to 40° and smaller than or equal to 60°. According to the method of manufacturing a display device in an embodiment, a third acute angle θ3 formed between the third sidewall SW3 and the substrate SS may be greater than or equal to 40° and smaller than or equal to 60°.

Referring to FIGS. 10D and 10E, a second photoresist PR2 may be formed on the first intermediate insulating layer MILD1. The second photoresist PR2 may have steep side surfaces 302 at positions corresponding to a second contact hole CNT2, a fifth contact hole CNT5, and a sixth contact hole CNT6. Subsequently, portions of the first intermediate insulating layer MILD1 and the first preliminary buffer layer PBF1 may be removed to form the lower insulating layer LIL in which the fifth contact hole CNT5 and the sixth contact hole CNT6 are defined.

Referring to FIG. 10F, which depicts step S400, an upper transistor TFT-U overlapping the non-display area NDA in a plan view, an upper insulating layer UIL, and capacitors CST1, CST2 overlapping the display area DA may be formed on the lower insulating layer LIL. The upper insulating layer UIL may include a second buffer layer BF2, a second insulating layer ILD2, and a second gate insulating layer GI2.

In an embodiment, the lower wiring layer BML1 may be formed on the barrier layer BAR, and an upper wiring layer BML2 may be formed on an interlayer insulating layer LID.

According to the method of manufacturing a display device in an embodiment, an active layer A2 of the upper transistor TFT-U may overlap the first contact hole CNT1 defined by the first sidewall SW1 and the third contact hole CNT3 defined by the third sidewall SW3, both having gradual slopes. Accordingly, the active layer A2 of the upper transistor TFT-U may have a planar shape and may be electrically stable.

In step S500, a display layer DL including a pixel electrode PE, a light-emitting layer EML, and a counter electrode CE may be formed in the display area DA.

According to the method of manufacturing a display device in an embodiment, a lower contact hole overlapping at least a portion of the active layer of the upper transistor in a plan view may be defined by a sidewall of the lower insulating layer having a gradual slope. As a result, the active layer of the upper transistor may have a planar shape and may be electrically stable. Additionally, transistors and wiring layers disposed in the non-display area of the substrate may be arranged to partially overlap with each other, and a contact hole that does not overlap the active layer of the upper transistor may be defined by a sidewall of the lower insulating layer having a steep slope. Thus, the area of the non-display region may be reduced, enhancing the reliability and improving the display quality of the display device.

A display device according to embodiments of the disclosure may be applied to various electronic devices. An electronic device according to an embodiment may include the above-described display device and may further include additional modules or components that provide supplementary functions beyond the display.

FIG. 11 is a block diagram of an electronic device according to an embodiment. Referring to FIG. 11, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data or information necessary for the operation of the processor 12 or the display module 11. When the processor 12 executes an application stored in the memory 13, image data signals and/or input control signals may be transferred to the display module 11 from the processor, and the display module 11 may process the received signals and output image information via a display screen.

The power module 14 may include a power supply module such as a power adapter or a battery device, and a power conversion module configured to convert the power supplied from the power supply module into power required for the operation of the electronic device 10.

At least one of the components of the electronic device 10 described above may be included within the display device according to the aforementioned embodiments. Additionally, some of individual modules functionally included in one module may be included in the display device, and some other may be provided separately from the display device. For example, the display device may include the display module 11, while the processor 12, memory 13, and power module 14 may be provided as components of another device within the electronic device 10 rather than within the display device itself.

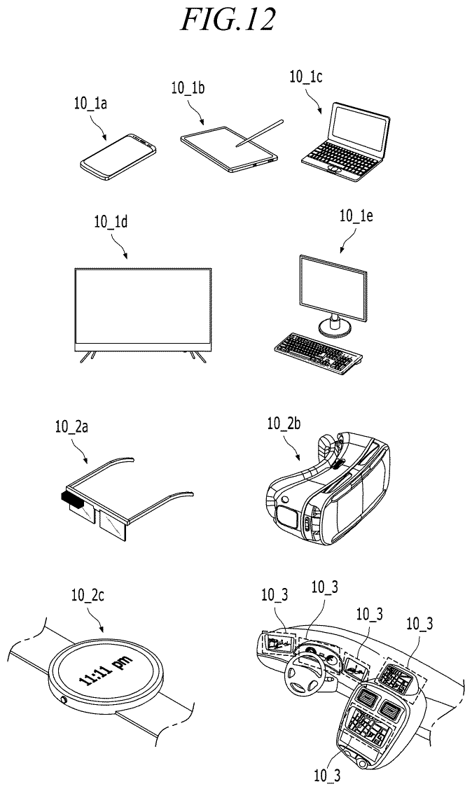

FIG. 12 illustrates schematic views of electronic devices according to various embodiments. Referring to FIG. 12, the display device according to the embodiments may be applied to a variety of electronic devices, including image display devices such as a smartphone 10_1a, tablet PC 10_1b, laptop computer 10_1c, TV 10_1d, and desktop monitor 10_1e, as well as wearable electronic devices that include display modules such as smart glasses 10_2a, head-mounted displays 10_2b, and smartwatches 10_2c. The electronic devices including the display device according to embodiments may further include automotive electronic devices 10_3 including display modules, such as center information displays (CID) on an instrument panel, center fascia, or dashboard of a vehicle, or room mirror displays.

While certain embodiments of the present disclosure have been described herein, those of ordinarily skilled in the art to which the present disclosure pertains shall appreciate that there may be a variety of modifications of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display device comprising:
a substrate including a display area and a non-display area adjacent to at least one side of the display area;
a first lower circuit layer disposed in the non-display area of the substrate, and comprising a lower transistor and a lower insulating layer; and
a first upper circuit layer disposed on the first lower circuit layer, and comprising an upper transistor and an upper insulating layer,
wherein a first contact hole is defined by a first sidewall of the lower insulating layer, and a second contact hole is defined by a second sidewall of the lower insulating layer,
wherein the first contact hole overlaps at least a portion of an active layer of the upper transistor, and the second contact hole does not overlap the active layer of the upper transistor, and
wherein a first acute angle formed between the first sidewall and the substrate is smaller than a second acute angle formed between the second sidewall and the substrate.

2. The display device of claim 1, wherein the first acute angle is greater than or equal to about 40° and smaller than or equal to about 60°.

3. The display device of claim 1, wherein the second acute angle is greater than or equal to about 70° and smaller than or equal to about 90°.

4. The display device of claim 1, wherein the first lower circuit layer further comprises a lower wiring layer disposed between the substrate and the lower transistor,
wherein the display device further comprises:
a first pattern connected, through the first contact hole, to at least one of a first portion of the lower transistor and the lower wiring layer; and
a second pattern connected, through the second contact hole, to at least one of a second portion of the lower transistor and the lower wiring layer.

5. The display device of claim 4, wherein the first pattern and the second pattern are provided as an integral structure.

6. The display device of claim 4, wherein at least a portion of the lower transistor overlaps the first contact hole, and
wherein at least a portion of the lower wiring layer overlaps the second contact hole.

7. The display device of claim 4, wherein at least a portion of the lower wiring layer overlaps the first contact hole, and
wherein at least a portion of the lower transistor overlaps the second contact hole.

8. The display device of claim 1, wherein the lower transistor includes a first lower transistor and a second lower transistor,
wherein at least a portion of the first lower transistor overlaps the first contact hole, and
wherein at least a portion of the second lower transistor overlaps the second contact hole.

9. The display device of claim 1, wherein a third contact hole is defined by a third sidewall of the lower insulating layer,
wherein the third contact hole overlaps at least a second portion of the active layer of the upper transistor,
wherein a first portion of the lower transistor overlaps the first contact hole,
wherein a second portion of the lower transistor overlaps the third contact hole, and
wherein a third acute angle formed between the third sidewall and the substrate is smaller than the second acute angle.

10. The display device of claim 1, wherein a fourth contact hole is defined by a fourth sidewall of the upper insulating layer,
wherein the fourth contact hole overlaps at least a portion of the active layer of the upper transistor, and
wherein a fourth acute angle formed between the fourth sidewall and the substrate is greater than the first acute angle.

11. The display device of claim 1, further comprising:
a second lower circuit layer disposed in the display area of the substrate, and comprising a pixel transistor and the lower insulating layer; and
a second upper circuit layer disposed on the second lower circuit layer, and comprising a capacitor and the upper insulating layer,
wherein a fifth contact hole is defined by a fifth sidewall of the lower insulating layer, and the fifth contact hole overlaps at least a portion of the capacitor, and
wherein a fifth acute angle formed between the fifth sidewall and the substrate is smaller than the second acute angle.

12. The display device of claim 1, further comprising:
a second lower circuit layer disposed in the display area of the substrate, and comprising a second lower transistor and the lower insulating layer; and
a second upper circuit layer disposed on the second lower circuit layer, and comprising a capacitor and the upper insulating layer,
wherein a fifth contact hole is defined by a fifth sidewall of the lower insulating layer, and the fifth contact hole overlaps at least a portion of the capacitor, and
wherein a fifth acute angle formed between the fifth sidewall and the substrate is greater than the first acute angle.

13. The display device of claim 1, wherein the upper transistor includes a first upper transistor and a second upper transistor,
wherein a sixth contact hole is defined by a sixth sidewall of the lower insulating layer,
wherein the first contact hole overlaps at least a portion of an active layer of the first upper transistor,
wherein the second contact hole overlaps at least a portion of an active layer of the second upper transistor, and
wherein a sixth acute angle formed between the sixth sidewall and the substrate is smaller than the second acute angle.

14. A method of manufacturing a display device, comprising:
preparing a substrate including a display area and a non-display area adjacent to at least one side of the display area;
forming a lower transistor and a preliminary lower insulating layer on the substrate, the lower transistor and the preliminary lower insulating layer overlapping the non-display area of the substrate;
forming a lower insulating layer including a first sidewall, by which a first contact hole is defined, and a second sidewall, by which a second contact hole is defined, by patterning the preliminary lower insulating layer; and
forming an upper transistor and an upper insulating layer on the lower transistor and the lower insulating layer,
wherein the first contact hole overlaps at least a portion of an active layer of the upper transistor, and the second contact hole does not overlap the active layer of the upper transistor, and
wherein a first acute angle formed between the first sidewall and the substrate is smaller than a second acute angle formed between the second sidewall and the substrate.

15. The method of claim 14, wherein the first acute angle is greater than or equal to about 40° and smaller than or equal to about 60°.

16. The method of claim 14, wherein the second acute angle is greater than or equal to about 70° and smaller than or equal to about 90°.

17. The method of claim 14, wherein the step of forming the first sidewall comprises:
forming a first preliminary photoresist on the preliminary lower insulating layer; and
heat-treating the first preliminary photoresist,
wherein an opening corresponding to the first contact hole is defined in the first preliminary photoresist.

18. The method of claim 17, wherein the step of forming the second sidewall comprises forming a second photoresist after heat-treating the first preliminary photoresist.

19. An electronic device comprising:
a processor; and
a display device receiving image data signal from the processor and providing image corresponding to the received image data signal,
wherein the display device comprises:
a substrate including a display area and a non-display area adjacent to at least one side of the display area;
a first lower circuit layer disposed in the non-display area of the substrate, and comprising a lower transistor and a lower insulating layer; and
a first upper circuit layer disposed on the first lower circuit layer, and comprising an upper transistor and an upper insulating layer,
wherein a first contact hole is defined by a first sidewall of the lower insulating layer, and a second contact hole is defined by a second sidewall of the lower insulating layer,
wherein the first contact hole overlaps at least a portion of an active layer of the upper transistor, and the second contact hole does not overlap the active layer of the upper transistor, and
wherein a first acute angle formed between the first sidewall and the substrate is smaller than a second acute angle formed between the second sidewall and the substrate.

20. The electronic device of claim 19, further comprising:
a memory storing data required for an operation of the display device or the processor; and
a power conversion module configured to generate or supply power.
